(19) United States
(12) Patent Application Publication
(10) Pub. No.: US 2026/0362660 A1
(43) Pub. Date: Nov. 12, 2026

(54) COOLING SYSTEM FOR POWER ELECTRONICS

(71) Applicant: Carrier Corporation, Palm Beach Gardens, FL (US)

(72) Inventors: Arindom Joardar, Jamesville, NY (US); Tobias Sienel, Baldwinsville, NY (US)

(21) Appl. No.: 19/687,817

(22) Filed: May 26, 2026

Related U.S. Application Data
(63) Continuation-in-part of application No. 18/405,259, filed on Jan. 5, 2024, now Pat. No. 12,660,138.
(60) Provisional application No. 63/479,110, filed on Jan. 9, 2023.

(51) Int. Cl. H05K 7/20

(52) U.S. Cl. CPC H05K 7/20927; H05K 7/20136; H05K 7/20209; H05K 7/20254; H05K 7/20272; H05K 7/20281; H05K 7/20327; H05K 7/20381; H05K 7/20909; H05K 7/20936

(57) ABSTRACT

A cooling system has a plurality of heat-generating devices including at least a first heat-generating device and a second heat-generating device and at least one heat sink to which the plurality of heat-generating devices are thermally coupled. The at least one heat sink includes at least one housing, a first fluid circuit associated with at least the first heat-generating device, and a second fluid circuit associated with at least the second heat-generating device. At least one heat exchanger is thermally coupled to the at least one heat sink.

### CROSS-REFERENCE TO RELATED APPLICATIONS

This Application claims the benefit of U.S. application No. Ser. No. 18/405,529 filed on Jan. 5, 2024, which claims the benefit of U.S. Provisional Application No. 63/479,110 , filed Jan. 9, 2023, the contents of which are incorporated by reference herein in their entirety.

### BACKGROUND

Exemplary embodiments pertain to the art of heat exchangers, and more particularly to heat exchangers for cooling power electronics.

Power electronics devices such as motor drives generate waste heat during operation of the device. Additionally, when the power electronics devices heat up, the operational efficiency of the devices can degrade adding to the amount of heat generated. When utilized in a refrigeration system to drive, for example, a compressor of the refrigeration system, effective thermal integration of these devices can be important aspect to the system's overall efficiency and reliability. Consequently, a goal of the system integrator is to maintain these components within a range of operating temperatures which will maximize the system efficiency. Accordingly, there remains a need in the art for heat exchangers configured to closely integrate with power electronic devices which can maintain optimal temperatures for these components under a variety of load conditions.

### BRIEF DESCRIPTION

According to an embodiment, a cooling system has a plurality of heat-generating devices including at least a first heat-generating device and a second heat-generating device and at least one heat sink to which the plurality of heat-generating devices are thermally coupled. The at least one heat sink includes at least one housing, a first fluid circuit associated with at least the first heat-generating device, and a second fluid circuit associated with at least the second heat-generating device. At least one heat exchanger is thermally coupled to the at least one heat sink.

In addition to one or more of the features described herein, or as an alternative, further embodiments may include at least one of the first fluid circuit and the second fluid circuit has a closed loop configuration.

In addition to one or more of the features described herein, or as an alternative, further embodiments may include the first fluid circuit and the second fluid circuit are arranged in parallel relative to a flow of heat transfer fluid.

In addition to one or more of the features described herein, or as an alternative, further embodiments may include the first fluid circuit and the second fluid circuit are fluidly coupled by at least one manifold.

In addition to one or more of the features described herein, or as an alternative, further embodiments may include a controller configured to selectively control a flow of a heat transfer fluid within the first fluid circuit and/or the second fluid circuit based on a thermal load at the first heat-generating device and the second heat-generating device.

In addition to one or more of the features described herein, or as an alternative, further embodiments may include that the at least one heat sink includes a first heat sink and a second heat sink and the at least one housing includes a first housing and a second housing. The first fluid circuit is formed in the first housing of the first heat sink and the second fluid circuit is formed in the second housing of the second heat sink.

In addition to one or more of the features described herein, or as an alternative, further embodiments may include the first housing is separate from the second housing.

In addition to one or more of the features described herein, or as an alternative, further embodiments may include the first housing is integrally formed with the second housing.

In addition to one or more of the features described herein, or as an alternative, further embodiments may include the at least one heat exchanger includes a first heat exchanger thermally coupled to the first fluid circuit and a second heat exchanger thermally coupled to the second fluid circuit.

In addition to one or more of the features described herein, or as an alternative, further embodiments may include the first heat exchanger and the second heat exchanger are arranged in parallel relative to a flow of a cooling fluid.

In addition to one or more of the features described herein, or as an alternative, further embodiments may include at least one sensor for monitoring one or more of: a thermal load at the at least one heat exchanger, an interface between the at least one heat sink and the at least one heat exchanger, and a temperature of at least one of the plurality of heat=generating devices.

In addition to one or more of the features described herein, or as an alternative, further embodiments may include at least one valve adjustable to control a flow of a cooling fluid provided to the first heat exchanger and to the second heat exchanger and a controller operable to adjust a position of the at least one valve based on data provided by the at least one sensor.

According to an embodiment, method of cooling a first heat-generating device and a second heat-generating device includes transferring heat from the first heat-generating device to a heat transfer fluid circulating within a first fluid circuit, transferring heat from the second heat-generating device to the heat transfer fluid circulating within a second fluid circuit, and transferring heat from the first fluid circuit and from the second fluid circuit to at least one cooling fluid at at least one heat exchanger thermally coupled to the first fluid circuit and the second fluid circuit.

In addition to one or more of the features described herein, or as an alternative, further embodiments may include that the at least one cooling fluid includes a primary cooling fluid and a secondary cooling fluid and the heat being transferred from the first fluid circuit and the second fluid circuit to the primary cooling fluid.

In addition to one or more of the features described herein, or as an alternative, further embodiments may include transferring heat from at least one of the first fluid circuit and the second fluid circuit to the at least one cooling fluid at the at least one heat exchanger thermally coupled to the first fluid circuit and the second fluid circuit includes vaporizing at least a portion of the primary cooling fluid within an inlet manifold of the at least one heat exchanger.

In addition to one or more of the features described herein, or as an alternative, further embodiments may include transferring heat from the secondary cooling fluid to the primary cooling fluid at the at least one heat exchanger.

In addition to one or more of the features described herein, or as an alternative, further embodiments may include the at least one heat exchanger includes a first heat exchanger thermally coupled to the first fluid circuit and a second heat exchanger thermally coupled to the second fluid circuit and the primary cooling fluid is provided to the first heat exchanger and the second heat exchanger in parallel.

In addition to one or more of the features described herein, or as an alternative, further embodiments may include sensing, via at least one sensor, at least one of a thermal load at the first heat exchanger, a thermal load at the second heat exchanger, a temperature of the first heat-generating device, a temperature of the second heat-generating device, a vapor quality of the primary cooling fluid output from the first heat exchanger, and a vapor quality of the primary cooling fluid output from the second heat exchanger.

In addition to one or more of the features described herein, or as an alternative, further embodiments may include adjusting, via a controller, at least one valve to control a flow of the primary cooling fluid to a first flow path associated with the first heat exchanger and a second flow path associated with the second heat exchanger.

In addition to one or more of the features described herein, or as an alternative, further embodiments may include the at least one valve is adjusted by the controller based on data from the at least one sensor.

### DETAILED DESCRIPTION OF THE DRAWINGS

The following descriptions should not be considered limiting in any way. With reference to the accompanying drawings, like elements are numbered alike:

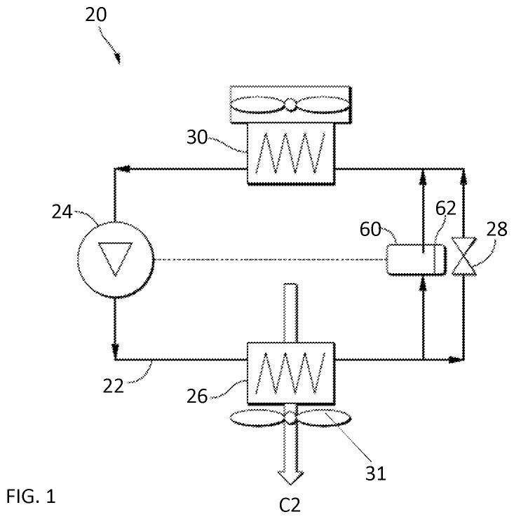

FIG. 1 is a schematic diagram of an example of a refrigeration system according to an embodiment;

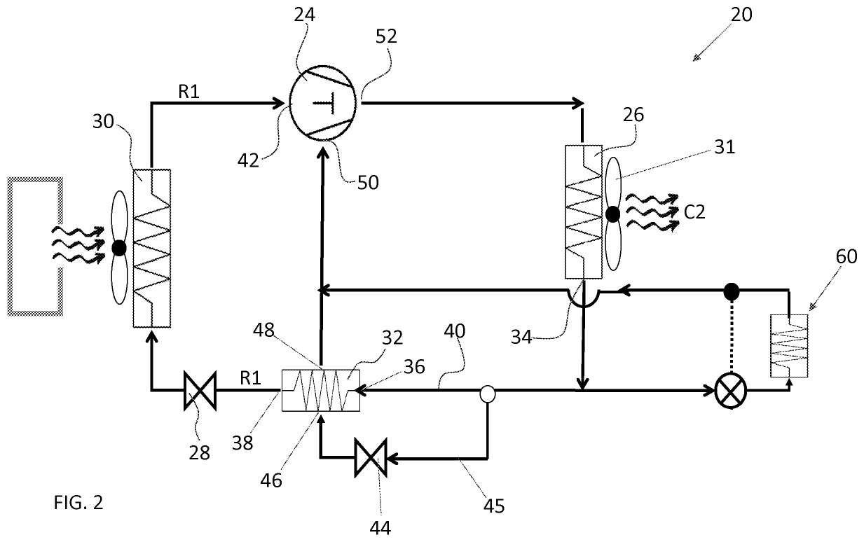

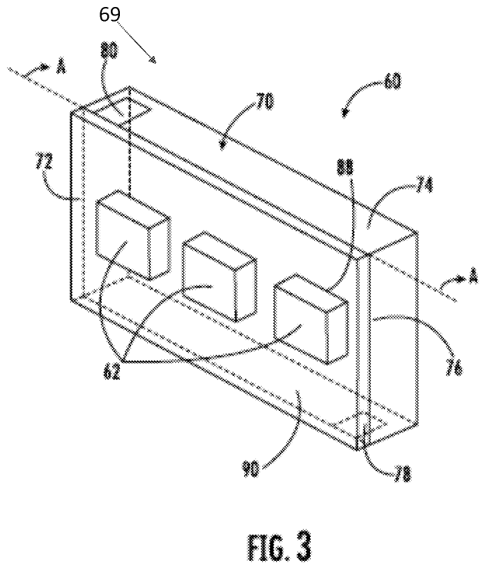

FIG. 2 is a schematic diagram of another example of a heating, ventilation, air conditioning and refrigeration (HVAC&R) system according to an embodiment;

FIG. 3 is an illustration of an embodiment of a cooling system for cooling a heat-generating device according to an embodiment;

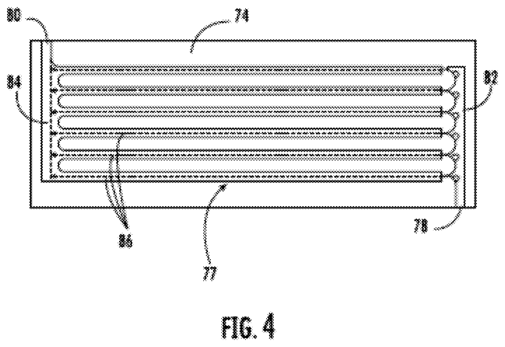

FIG. 4 is a cross-sectional view of the housing of the cooling system of FIG. 3 according to an embodiment;

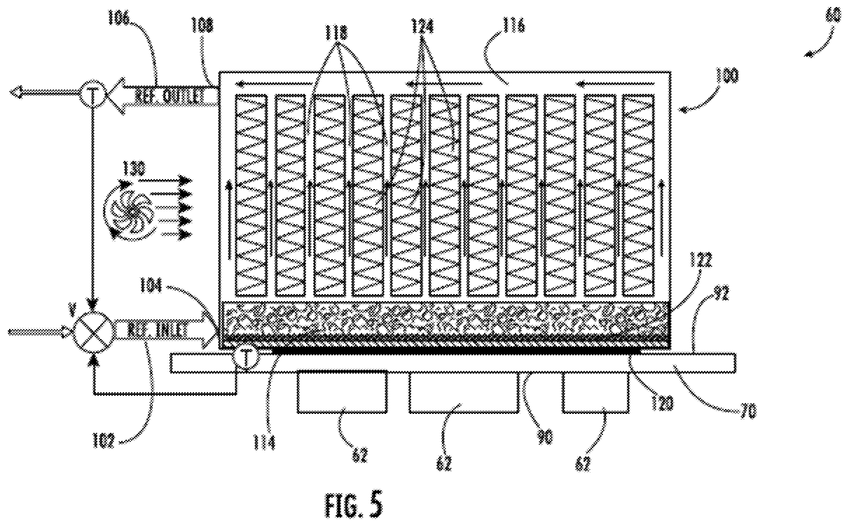

FIG. 5 is front view of a cooling system according to another embodiment;

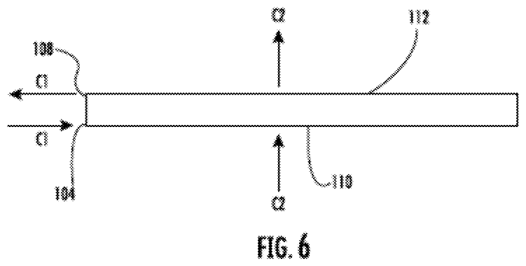

FIG. 6 is a plan view of the heat exchanger of the cooling system of FIG. 5 according to an embodiment;

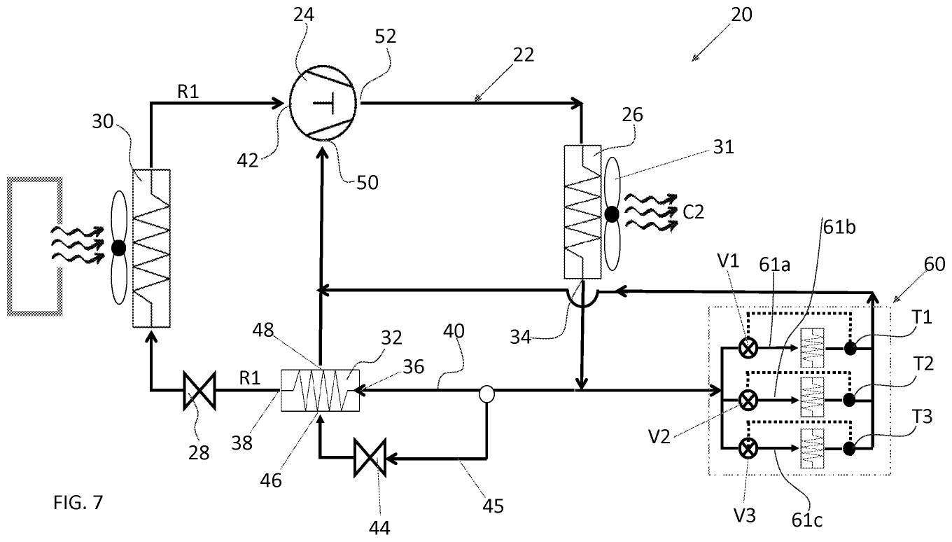

FIG. 7 is a schematic diagram of another example of a heating, ventilation, air conditioning and refrigeration (HVAC&R) system according to another embodiment;

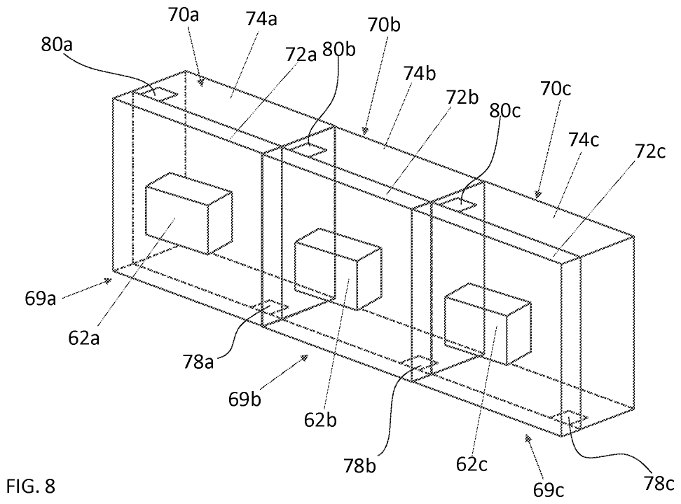

FIG. 8 is a perspective view of a plurality of heat sinks of the cooling system of FIG. 7 according to an embodiment;

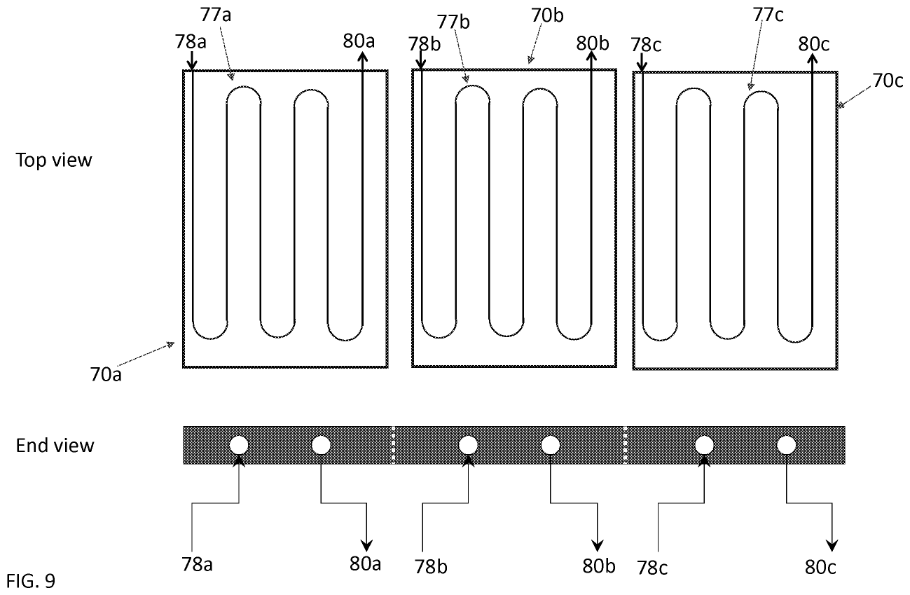

FIG. 9 is a cross-sectional view and top view of the plurality of heat sinks of FIG. 8 according to an embodiment;

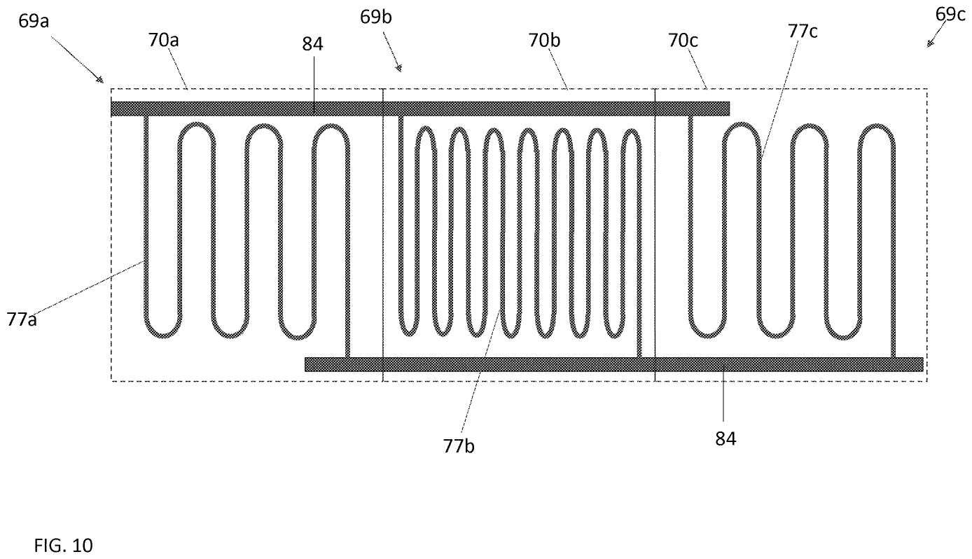

FIG. 10 is a cross-sectional view of the plurality of heat sinks of FIG. 8 according to another embodiment;

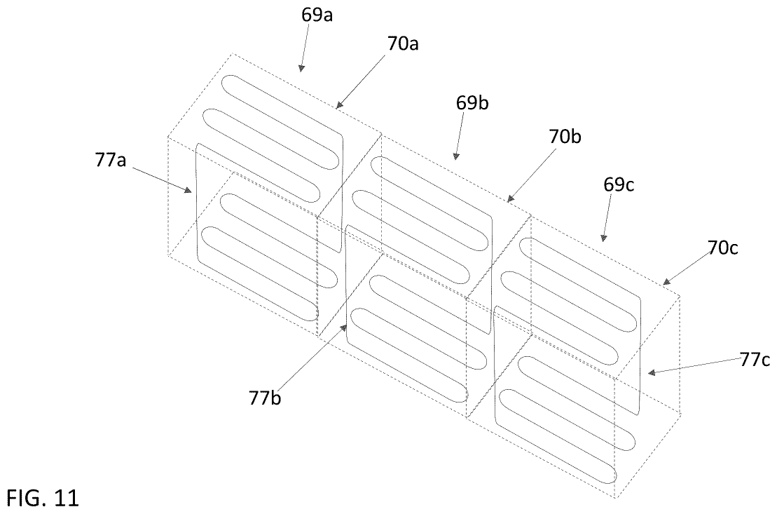

FIG. 11 is a perspective view of the plurality of heat sinks of FIG. 8 according to another embodiment; and

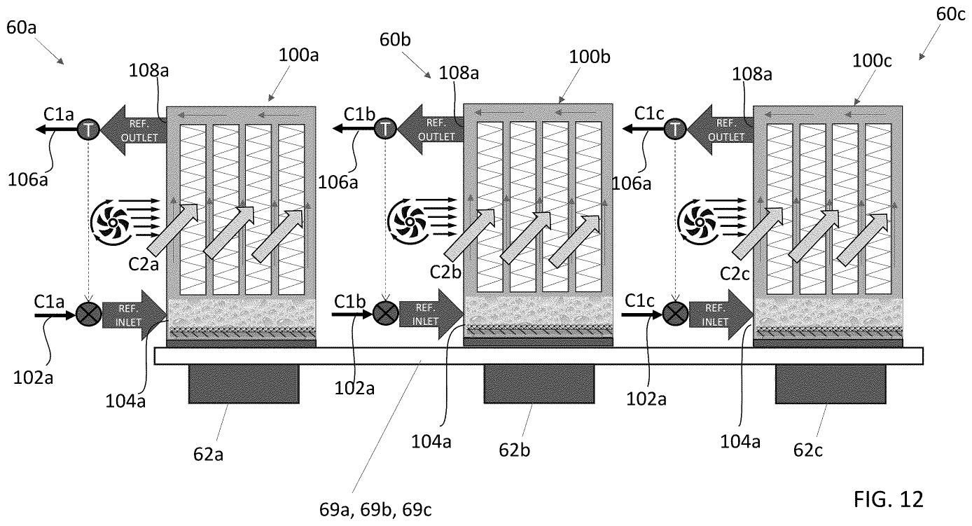

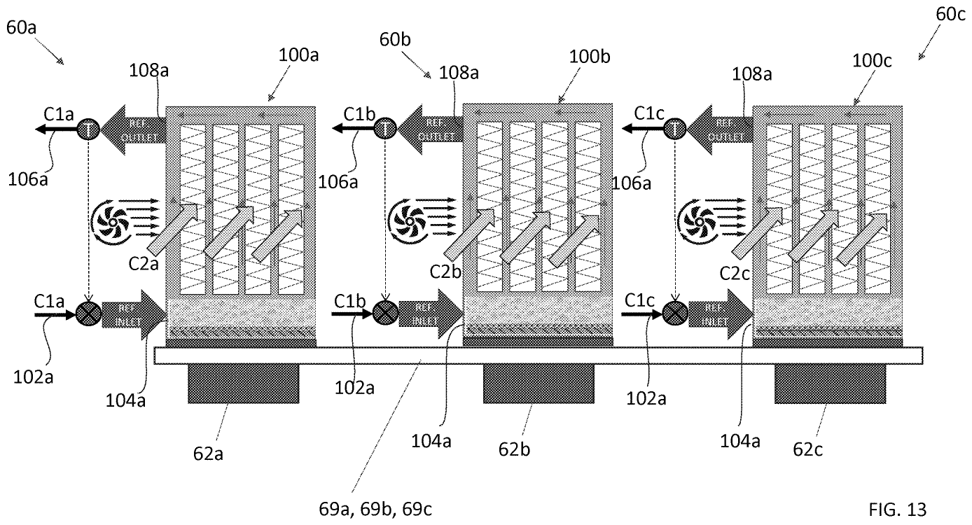

FIG. 12 is front view of the cooling system of FIG. 7 according to an embodiment.

### DETAILED DESCRIPTION

A detailed description of one or more embodiments of the disclosed apparatus and method are presented herein by way of exemplification and not limitation with reference to the Figures.

Referring to FIG. 1, an example of a refrigeration system, such as a heating, ventilation, air conditioning and refrigeration (HVAC) system 20 is schematically illustrated. Exemplary refrigeration systems 20 include, but are not limited to, residential, split, packaged, chiller, rooftop, supermarket, transport and fuel cell systems, for example. In the illustrated, non-limiting embodiment, the refrigeration system 20 includes a refrigeration circuit 22 including a compressor 24, a condenser 26, an expansion device 28 and an evaporator 30 arranged in series and having a volume of refrigeration fluid, such as refrigerant for example, flowing therethrough.

Another example of a refrigeration system 20 is illustrated in FIG. 2. In addition to the compressor 24, condenser 26, expansion device 28, and evaporator 30 previously described the refrigeration circuit 22 includes an economizer heat exchanger 32. The economizer heat exchanger 32 may be positioned between the condenser 26 and the expansion device 28 relative to a flow of refrigeration fluid through the refrigeration circuit 22. Although the economizer heat exchanger 32 is illustrated as being located directly downstream from the outlet 34 of the condenser 26, it should be understood that embodiments where one or more other components of the refrigeration system 20 are located between the condenser 26 and an inlet of the economizer heat exchanger 32 are also contemplated herein.

In an embodiment, the economizer heat exchanger 32 is a brazed plated fin heat exchanger. However, other suitable types of heat exchangers are also within the scope of the disclosure. Further, the economizer heat exchanger 32 is a refrigeration fluid-refrigeration fluid heat exchanger and therefore has a plurality of distinct fluid flow paths formed therein. In the illustrated, non-limiting embodiment, the economizer heat exchanger 32 has a first flow path and a second flow path, respectively.

In the illustrated, non-limiting embodiment, the inlet 36 of the first flow path of the economizer heat exchanger 32, also referred to herein as the “main flow path,” is arranged in direct fluid communication with an outlet 34 of the condenser 26. Alternatively, or in addition, the outlet 38 of the main flow path of the economizer heat exchanger 32 may be arranged directly upstream from and in fluid communication with an inlet of the expansion device 28.

In operation, a first portion R1 of the refrigeration fluid output from the condenser 26 is provided to the main flow path of the economizer heat exchanger 32 via a main conduit 40. Although the main flow path is illustrated as a single pass through the economizer heat exchanger 32, it should be understood that in other embodiments the main flow path may include a plurality of passes through the economizer heat exchanger 32. At the outlet 38 of the main flow path of the economizer heat exchanger 32, the first portion R1 of the refrigeration fluid is configured to flow to the expansion device 28. From the expansion device 28, the refrigeration fluid is expanded within the evaporator 30. The first portion R1 of refrigeration fluid output from the evaporator 30 is provided via a first compressor inlet path to a primary suction inlet 42 of the compressor 24. Accordingly, the fluid loop of the first portion R1 of the refrigeration fluid includes the compressor 24, condenser 26, main flow path of the economizer heat exchanger 32, expansion device 28, and the evaporator 30.

An economizer expansion device 44 may be arranged within the refrigeration circuit 22 in fluid communication with the condenser 26. The economizer expansion device 44 is operable to expand and cool the refrigeration fluid provided thereto. Although the economizer expansion device 44 is illustrated as being disposed within an economizer conduit 45 fluidly coupled to an extending from the main conduit 40 at a location upstream from the first inlet 36, it should be understood that an economizer conduit 45 fluidly connected to the outlet 34 of the condenser 26 in another suitable manner is also contemplated herein.

Located downstream from the economizer expansion device 44 is the inlet 46 of a second flow path of the economizer heat exchanger 32, also referred to herein as the “economizer flow path.” Further, the outlet 48 of the second flow path of the economizer heat exchanger 32 may, but need not be directly connected to an economizer inlet or port 50 of the compressor 24. In the illustrated, non-limiting embodiment, the inlet 36 of the main flow path and the inlet 46 of the economizer flow path are arranged at adjacent sides of the economizer heat exchanger 32. However, in other embodiments, it should be understood that the inlets 36, 46 of both flow paths could alternatively be arranged at the same side of the economizer heat exchanger 32 or at opposite sides thereof. Similarly, the outlets 38, 48 of both the main flow path and the economizer flow path may be arranged at opposite sides, the same side, or adjacent sides depending on the desired flow configuration of the economizer heat exchanger 32. Further, although the economizer flow path is illustrated as a single pass, it should be understood that in some embodiments, the economizer flow path may include a plurality of passes through the economizer heat exchanger 32.

Within the economizer flow path, a second portion R2 of the refrigeration fluid is configured to absorb heat from the first portion R1 of the refrigeration fluid within the main flow path, thereby cooling the first portion R1 of the refrigeration fluid. As a result of this heat transfer, the second portion R2 of the refrigeration fluid within the economizer flow path may become a vapor. From the outlet 48 of the economizer flow path, the second portion R2 of the refrigeration fluid is provided to the economizer suction inlet 50 located at an intermediate portion of the compressor 24. Accordingly, the second portion R2 of the refrigeration fluid bypasses the expansion device 28 and the evaporator 30 of the refrigeration circuit 22. Within the compressor 24 the first portion R1 and the second portion R2 of refrigeration fluid are mixed before being provided to the discharge port 52 to repeat the cycle. Accordingly, the fluid loop of the second portion R2 of the refrigeration fluid includes the compressor 24, condenser 26, economizer expansion device 44, and economizer flow path of the economizer heat exchanger 32. It should be understood that the refrigeration systems 20 illustrated and described herein are intended as an example only, and that a refrigeration system 20 having another configuration is within the scope of the disclosure.

With continued reference to both FIGS. 1 and 2, in an embodiment, the refrigeration system 20 includes at least one cooling system 60 for cooling one or more heat-generating devices 62. The term “heat-generating device” as used herein can refer to any electronic component which generates heat during operation thereof. Examples of a heat-generating device 62 include, but are not limited to a processor, power electronic devices, or another device that can provide a controlled output power by modulating and/or converting a supplied input power (e.g., a variable frequency drive, power rectifier, power converter, and the like). Such a heat-generating device 62 can be used to control the speed of a compressor and/or the speed of a fan associated with of a refrigeration system based on various predetermined system conditions. In an embodiment, the at least one heat-generating devices 62 includes a variable frequency drive operably coupled to the compressor 24 of the refrigeration system 20.

With reference now to FIG. 3, an example of at least a portion of a cooling system 60 for cooling one or more heat-generating devices 62 is illustrated. As shown, the cooling system 60 may include a heat sink 69 having a housing 70 formed from a heat conductive material, such as a metal material. For example, the housing 70 may be formed from any suitable metal, e.g., aluminum, aluminum alloy, steel, steel alloy, copper, copper alloy, or the like. In the illustrated, non-limiting embodiment, the housing 70 is formed from a plurality of housing portions, such as a first housing portion 72, and a second housing portion 74, joined along corresponding mating surfaces to form a seam 76 therebetween. In such embodiments, the first and second housing portions 72, 74 can abut one another along a side and can be joined using any suitable means such as brazing, welding, clamping, compressing, bolting, and the like. Although two housing portions 72, 74 are illustrated in the exemplary embodiments, it should be understood that a housing 70 formed from any number of housing portions including a single housing portion, or more than two housing portions for example, are within the scope of the disclosure.

The mating surfaces of the first and second housing portions 72, 74 may be configured to correspond to one another, e.g., to fit together to seal a fluid circuit therebetween (the fluid circuit to be described in more detail below). In an embodiment, the mating surfaces of the first and second housing portions 72, 74 include precision surfaces formed from a process having highly accurate and precise dimensional control, such as through computer numerical control (CNC) machining process and/or net shape, or near net shape manufacturing process. Optionally a sealing material can be disposed between the first and second housing portions 72, 74 to aide in preventing leakage from the fluid circuit. As shown in FIG. 3, in an embodiment, each of the first housing portion 72 and the second housing portion 74 is formed as a substantially solid plate. However, embodiments where one or more of the housing portions 72, 74 has another configuration are also contemplated herein.

In an embodiment, a fluid circuit 77 (see FIG. 4) is formed within a portion of the housing 70, such as between the first and second housing portions 72, 74. In such embodiments, the heat sink 69 may be considered a cold plate. The fluid circuit 77 includes a fluid inlet 78 and fluid outlet 80 formed in the housing 70. The fluid inlet 78 and the fluid outlet 80 can be any shape, including the shape of a circle, oval, triangular, square, rectangular, or any simple polygonal shape or portion thereof. Further, the perimeter of one or both of the fluid inlet 78 and the fluid outlet 80 can be formed by a recess in at least one or both of the housing portions 72, 74. The recess may extend to an edge of a respective housing portion, may be arranged centrally relative to a housing portion, or may overlap with the seam 76 defined between two adjacent housing portions 72, 74.

An example of a fluid circuit 77 is best illustrated in the cross-sectional view of the heat sink 69 shown in FIG. 4. In an embodiment, the fluid circuit 77 includes a single continuous flow path extending between and fluidly coupling the inlet 78 and the outlet 80. However, in other embodiments, as shown in the FIG., in addition to the inlet 78 and the outlet 80, the fluid circuit 77 may include a first or inlet manifold 82, a second or outlet manifold 84, and a plurality of fluid passages 86 connecting the first and second manifolds 82, 84. The fluid inlet 78 can be configured to connect a heat transfer fluid source to the inlet manifold 82 using any suitable mechanical connection. Similarly, the fluid outlet 80 can be configured to connect a heat transfer fluid sink to the outlet manifold 84 using any suitable mechanical connection (e.g., compression coupling, brazing, welding, and the like). In an embodiment, the heat transfer fluid configured to flow through the fluid circuit 77 is the refrigeration fluid circulating within the refrigeration circuit 22. For example, the heat transfer fluid source may be the condenser of the refrigeration system 20 and the heat transfer fluid sink may be the evaporator 30. However embodiments where the heat transfer fluid is separate from the refrigeration fluid of the refrigeration system 20 are also contemplated herein.

One or more of the inlet manifold 82, the outlet manifold 84, and the plurality of fluid passages 86 may be formed as a recess in at least one of the first housing portion 72 and the second housing portion 74. In an embodiment, the inlet manifold 82, the outlet manifold 84, and the plurality of fluid passages 86 are formed as a plurality of connected recesses in at least one housing portion, such as the second housing portion 74 for example. Accordingly, the plurality of recesses form the fluid circuit 77 disposed between the first and second housing portions 72, 74 when the housing portions 72, 74 are joined. For example, a first housing portion 72 having a plurality of connected recesses can be joined to a flat, second housing portion 74 that does not have any recesses formed therein. In another embodiment, a first housing portion 72 and a second housing portion 74 can each have a plurality of connected recesses which mirror one another such that when the first and second housing portions 72, 74 are joined, the connected recesses form the fluid circuit 77. The plurality of connected recesses can have any shape in the depth dimension (e.g., as projected into the plate), including semi-circular, semi-oval, triangular, square, rectangular, or any simple polygonal shape or portion thereof.

The mating surfaces of the first and second housing portions 72, 74 can substantially border the plurality of connected recesses. Optionally, the mating surfaces can include raised or recessed portions, or other engagement features to aid in alignment of the housing portions 72, 74 prior to joining. However, it should be appreciated that embodiments where the heat sink 69 does not include a fluid circuit extending therethrough or formed therein are also within the scope of the disclosure.

With reference again to FIG. 3, the one or more heat-generating devices 62 to be cooled by the cooling system 60 may be mounted directly or indirectly to a surface 90 of the housing 70 of the heat sink 69, such as of the first housing portion 72 for example. The at least one heat-generating device 62 may be mounted to the housing 70 in any suitable manner that facilitates the transfer of thermal energy from the heat-generating device 62 to the housing 70. Because electrical components inside the heat-generating device 62 can generate a large amount of heat, each heat-generating device 62 may have an interface 88 which is designed for attachment to the heat sink 69. In an embodiment, a thermal interface material 120 is arranged between the heat sink interface 88 and the adjacent surface 90 of the housing 70 of the heat sink 69 to facilitate the transfer of heat from the at least one heat-generating device 62 to the heat sink 69. As used herein the term “thermal interface material” is intended to include any material that is thermally conductive material. Examples of a thermal interface material include, but are not limited to thermal paste, thermal grease, thermal pads, such as formed from silicone, sponge, or polymers filled with thermally conductive particles, thermal tape, diamond, or a component including diamond. In an embodiment, the thermal interface material includes glass. When the heat-generating devices 62 are thermally coupled to the cooling system 60, the heat generated by the heat-generating devices 62 is at least partially transferred to the heat sink 69 of the cooling system 60 via the heat sink interface 88 to keep the one or more heat-generating devices 62 cooled below a maximum allowable operating temperature (e.g., 150° C.).

In embodiments where the heat sink 69 is a cold plate, one or more fluid passages 86 of the fluid circuit 77 may be positioned to perform localized cooling at the area of the housing 70 with the greatest heat flux, such as at the area directly aligned with or in overlapping arrangement with a heat-generating device 62. Accordingly, the at least one fluid passage 86 may be associated with a heat-generating device 62. In embodiments where the housing 70 is associated with a plurality of heat-generating devices 62, one or more fluid passages 86 may be associated with and configured to remove heat from a respective heat-generating device 62. More specifically, the at least one fluid passage 86 associated with a respective heat-generating device 62 may be physically located within the housing 70 in alignment with the heat-generating device 62.

With reference now to FIG. 5, in an embodiment, the cooling system 60 additionally includes a heat exchanger 100 mounted in an axially overlapping relationship with and thermally coupled to the at least one heat-generating device 62. Although only a single heat exchanger 100 is illustrated in the FIGS., it should be appreciated that a plurality of heat exchangers may be included to increase the heat transfer that occurs therein. In an embodiment, the heat exchanger 100 is thermally coupled to heat sink 69, such as to a second surface 92 of the housing 70 thereof. Although the heat exchanger 100 is illustrated as being located opposite the at least one heat-generating device 62 about the housing 70, embodiments where the heat exchanger 100 is thermally coupled to a side of the housing 70 located adjacent to the side at which the at least one heat-generating device 62 is mounted are also contemplated herein.

In the illustrated, non-limiting embodiment, an inlet conduit 102 is fluidly connected to a first fluid inlet 104 of the heat exchanger 100 and an outlet conduit 106 is fluidly connected to a first fluid outlet 108 of the heat exchanger 100 to form a flow path of a primary cooling fluid C1. The heat exchanger additionally includes a second fluid inlet 110 (see FIG. 6) connected to a second fluid outlet 112 to define a flow path of a secondary cooling fluid C2. In embodiments where the housing 70 is a cold plate, the primary cooling fluid C1 and/or the secondary cooling fluid C2, may be the same or may be distinct or different from the heat transfer fluid provided to the fluid circuit 77.

In an embodiment, the body of the heat exchanger 100 includes an inlet manifold 114 defining the first fluid inlet 104 and an outlet manifold 116 defining the first fluid outlet 108. The inlet manifold 114 and the outlet manifold 116 are fluidly connected via at least one, and in some embodiments, a plurality of heat exchanger tubes 118. In an embodiment, the inlet manifold 114 is positioned directly adjacent to the surface 92 of the heat sink 69 and is thermally coupled thereto via a thermal interface material 120.

The heat exchanger 100 may be a microchannel heat exchanger having a plurality of substantially parallel microchannel heat exchange tubes 118 (see FIG. 6), each defining a plurality of fluid flow paths (not shown). However, examples of other types of heat exchangers that may be used, include, but are not limited to, microtube, double pipe, shell and tube, tube and fin, plate, plate and shell, adiabatic shell, plate fin, pillow plate, and fluid heat exchangers. The type of heat exchanger 100 selected may depend at least in part based on the type of primary and secondary cooling fluids C1, C2 being provided thereto.

In the illustrated, non-limiting embodiment of FIG. 5, the cooling system 60 includes a single heat exchanger 100 associated with each of the three illustrated heat-generating devices 62. However, in other embodiments, a distinct heat exchanger 100 may be associated with each heat-generating devices 62. In such embodiments, the primary cooling fluid C1 may be configured to flow through each of the plurality of heat exchangers in parallel or in series.

The primary cooling fluid C1 and the secondary cooling fluid C2 are arranged in a heat exchange relationship at the heat exchanger 100. In an embodiment, the heat exchanger 100 is configured as an evaporator and the primary cooling fluid C1 provided to heat exchanger 100 is configured to absorb heat from the secondary cooling fluid C2. In the illustrated, non-limiting embodiment, the secondary cooling fluid C2 is a flow of air moved by a fan 130. However, in other embodiments, another movement mechanism, such as a pump or some other component may be used to circulate the secondary cooling fluid C2 through the heat exchanger and across the peripheral heat-generating devices. Further, it should be understood that any fluid, including a liquid, may be used as the secondary cooling fluid. In the non-limiting embodiment illustrated in FIG. 5, the heat exchanger 100 has a single pass configuration for both the primary cooling fluid C1 and the secondary cooling fluid C2. However, in other embodiments, at least one of the primary and secondary cooling fluids C1, C2 may make multiple passes through the heat exchanger 100. Further, the primary and secondary cooling fluids C1, C2 may be arranged in any suitable flow configuration at the heat exchanger, such as a cross-flow, a parallel flow, a counter-flow, or any combination thereof.

In operation, the method of cooling the at least one heat-generating device includes transferring heat from the at least one heat-generating device to the heat sink 69. The method additionally includes providing the primary cooling fluid C1, such as a refrigeration fluid or refrigerant for example, from the inlet conduit 102 into the inlet manifold 114 of the heat exchanger 100. The primary cooling fluid C1 provided to the inlet manifold 114 may be a liquid, or alternatively, may be a two-phase mixture of liquid and vapor. Within the inlet manifold 114, at least a portion of the heat transferred to the heat sink 69 from the at least one heat-generating device 62 is transferred from the second surface 92 of the housing 70 of the heat sink 69 to the primary cooling fluid C1. The heat transferred to the primary cooling fluid C1 within the inlet manifold 114 causes the temperature of the primary cooling fluid C1 to increase, and in some embodiments, causes at least a portion of the primary cooling fluid C1 within the inlet manifold 114 to vaporize.

In an embodiment, a surface 122 of the heat exchanger 100, such as a surface of the inlet manifold 114 located adjacent to the surface 92 of the heat sink 69 for example, is optimized to facilitate boiling, such as nucleate boiling for example, of the primary cooling fluid C1 within the inlet manifold 114. This optimization may include the formation of a specific microstructure at the surface 122. In an embodiment, this optimization is performed via application a coating or film applied to the surface 122. Alternatively, this optimization may be performed via a machining process or another suitable manufacturing process. However, it should be appreciated that the enhanced or optimized surface 122 intended to facilitate boiling of the primary cooling fluid C1 is not required, and in some embodiments is not present within heat exchanger 100.

As the primary cooling fluid C1 vaporizes, the gaseous primary cooling fluid having some liquid primary cooling fluid entrained therein flows through the plurality of heat exchange tubes 118 of the heat exchanger 100 toward the outlet manifold 116 of the heat exchanger 100. In the illustrated, non-limiting embodiment, the secondary cooling fluid C2 is configured to flow through the gaps or passages 124 defined between adjacent heat exchange tubes 118. As the secondary cooling fluid moves through the plurality of passages 124, heat from the secondary cooling fluid C2 is transferred to the primary cooling fluid C1, causing at least some of the liquid primary cooling fluid C1 within the heat exchange tubes 118 to vaporize.

In an embodiment, the movement mechanism 130 operable to move the secondary cooling fluid C2 through the heat exchanger 100 includes a fan 31 associated with the condenser 26 of the refrigeration system, and the secondary cooling fluid C2 is the flow of air exhausted from the condenser 26. However, it should be understood that the fan may be associated with another component of the refrigeration system 20, or alternatively, may be dedicated solely to the movement of the secondary cooling fluid C2 through the heat exchanger 100. Further, it should be understood that any fluid, including a liquid, may be used as the secondary cooling fluid. For example, the secondary cooling fluid C2 may be a liquid or a two-phase fluid. Further, it should be appreciated that in embodiments where a liquid is used as the secondary cooling fluid C2, use of a heat exchanger having another configuration may be required.

The heated primary cooling fluid C1 received within the outlet manifold 116 and output from the first fluid outlet 108 of the heat exchanger 100 may include a greater amount of vapor than the primary cooling fluid C1 provided to the first fluid inlet 104 of the heat exchanger 100. In an embodiment, the primary cooling fluid C1 provided to the first fluid outlet 108 of the heat exchanger is primarily vapor, if not entirely vapor. In embodiments where the heated primary cooling fluid C1 is the refrigeration fluid of the refrigeration system 20, the primary cooling fluid C1 output from the first fluid outlet 108 may be delivered to another component of the refrigeration system 20. The cooled secondary cooling fluid C2 provided at the second fluid outlet 112 of the heat exchanger 100 may be exhausted out of the cooling system 60 and/or may be used to cool another heat-generating device 62 or other component within the refrigeration system 20. For example, the cooled secondary cooling fluid C2 may be used to absorb heat from the refrigeration fluid at the condenser 26.

As best shown in FIG. 5, at least one valve V may be arranged within the inlet conduit 102 and/or the outlet conduit 106 to control the flow of the primary cooling fluid C1 to and/or from the heat exchanger 100. In an embodiment, the position of the valve V and therefore the flow through the heat exchanger 100, is actively managed based on a thermal load at the heat exchanger 100. The thermal load may be determined on information collected by one or more sensors, represented schematically at T. In the illustrated, non-limiting embodiment, a first sensor is operable to monitor the temperature of the heat sink 69, and a second sensor is operable to monitor the temperature of the primary cooling fluid C1 at the outlet conduit 106. It should be appreciated that the at least one sensor T may be operable to measure temperature directly or indirectly. Further, the at least one sensor may be configured to monitor another parameter, such as humidity for example. In an embodiment, the valve V is operated to control the temperature of at least one of the primary and secondary cooling fluids C1, C2 output from the heat exchanger 100 to prevent the formation of condensation on the exterior surface of the heat exchange tubes 118.

Another example of a refrigeration system 220 is illustrated in FIG. 7. The refrigeration system 220 may be substantially identical to the refrigeration system 220 of FIG. 2. Unlike the embodiment illustrated in FIG. 2 in which a single flow path through the cooling system 60 is shown fluidly connected to the closed loop circuit of the refrigeration system 20, in the non-limiting embodiment of FIG. 7, the cooling system 60 includes a plurality of flow paths 61a, 61b, 61c fluidly connected to the fluid loop of the refrigeration system 20 in parallel. It should be appreciated that each flow path of the cooling system 60 may be associated with one or more heat-generating devices 62, such as the heat-generating devices of a server, a server rack, or a server cabinet within a data center. As shown, the flow path of the refrigerant circuit 22 separates into three parallel flow paths 61a, 61b, 61c at a location downstream from the condenser 26, and in parallel with the economizer heat exchanger 32 and an economizer expansion valve 44. Although a cooling system 60 having three parallel flow paths 61a, 61b, 61c is illustrated, it should be appreciated that embodiments having two parallel flow paths, and embodiments having more than three parallel flow paths are also contemplated herein.

Similar to the embodiment illustrated and described with reference to FIGS. 2-5, each flow path of the cooling system 60 may have a heat sink 69a, 69b, 69c associated therewith for cooling the at least one heat-generating device 62a,62b, 62c. Accordingly, the first flow path 61a may include a first heat sink 69a associated with a first heat-generating device 62a, the second flow path 61b may include a second heat sink 69b associated with a second heat-generating device 62b, and the third flow path 61c may include a third heat sink 69c associated with a third heat-generating device 62c. The one or more heat-generating devices 62a, 62b, 62c to be cooled by the cooling system 60 may be mounted directly or indirectly to a surface of a respective heat sink 69a, 69b, 69c. Each heat sink 69a, 69b, 69c may have a configuration as previously described with reference to FIGS. 1-5. For example, each heat sink 69a, 69b, 69c may have a respective housing 70a, 70b, 70c, and in some embodiments, each housing 70a, 70b, 70c includes a first housing portion 72a, 72b, 72c and a second housing portion 74a, 74b, 74c mated therewith. It should be appreciated that the housings 70a, 70b, 70c of the heat sinks 69a, 69b, 69c may be separate from one another, or alternatively may be integrally formed as a unitary component.

In an embodiment, at least one of the heat sinks 69a, 69b, 69c is configured as a cold plate. For example, the first heat sink 69a may include a first fluid circuit 77a, the second heat sink 69b may include a second fluid circuit 77b, and/or the third heat sink 69c may include a third fluid circuit 77c. Each fluid circuit 77a, 77b, 77c may be formed in a single housing portion 72a, 74a, 72b, 74b, 72c, 74c, or alternatively, may be formed by the paired housing portions 72a, 74a, 72b, 74b, 72c, 74c in combination. A fluid circuit 77a, 77b, 77c having any suitable configuration is contemplated herein. For example, a fluid circuit 77a, 77b, 77c may have a single flow path, or a plurality of parallel flow paths. In the illustrated, non-limiting embodiment of FIGS. 8-9, each fluid circuit 77a, 77b, 77c includes a respective fluid inlet 78a, 78b, 78c and a respective fluid outlet 80a, 80b, 80c formed in the housing 70a, 70b, 70c. Accordingly, the fluid circuits 77a, 77b, 77c are generally fluidly separate from one another within the heat sinks 69a, 69b, 69c and may be considered to be “open circuits.” In other embodiments, such as shown in FIG. 10, the plurality of fluid circuits 77a, 77b, 77c may be fluidly connected by an inlet manifold 82 and an outlet manifold 84 such that a heat transfer fluid is configured to flow through each of the plurality of fluid circuits 77a, 77b, 77c in parallel is also contemplated herein. In such embodiments, the housings 70a. 70b, 70c of the heat sinks 69a, 69b, 69c may be integrally formed.

The heat transfer fluid configured to flow through the fluid circuit 77a, 77b, 77c of one or more of the heat sinks 69a, 69b, 69c of the cooling system 60 may be the refrigeration fluid R circulating within the refrigeration circuit 22. In such an embodiment, the heat transfer fluid source configured to deliver a fluid flow to one or more of the fluid inlets 78a, 78b, 78c may be the condenser 26 of the refrigeration system 20 and each of the heat sinks 69a, 69b, 69c may function as an evaporator. However, embodiments where the heat transfer fluid is different from the refrigeration fluid R and/or fluidly separate from the refrigeration circuit 22 are also contemplated herein.

With reference to FIG. 11, in an embodiment, one or more of the fluid circuits 77a, 77b, 77c has a closed loop configuration contained within a respective housing 70a, 70b, 70c. For example, a first portion of the fluid circuit 77a, 77b, 77c may be located within the housing 70a, 70b, 70c proximate an interface between the heat sink 69a, 69b, 69c and the heat-generating device 62a, 62b, 62c such that heat from the heat-generating device 62a, 62b, 62c is absorbed by the heat transfer fluid within the first portion. Similarly, a second portion of the fluid circuit 77a, 77b, 77c may be proximate an interface between the heat sink 69a, 69b, 69c and a respective heat exchanger 100a, 100b, 100c, to be described in more detail below. At the second portion of the fluid circuit 77a, 77b, 77c, heat may be exhausted from the heat transfer fluid to a cooling fluid within the heat exchanger 100a, 100b, 100c.

The cooling system 60 includes at least one heat exchanger thermally coupled to the plurality of heat-generating devices 62a, 62b, 62c. As best shown in FIG. 12, each flow path 61a, 61b, 61c of the cooling system 60 may include a respective heat exchanger 100a, 100b, 100c thermally coupled to the at least one heat-generating device 62a, 62b, 62c associated with each flow path of the cooling system 60. Although only a single heat exchanger 100a, 100b, 100c is illustrated at each flow path 61a, 61b, 61c, it should be appreciated that in other embodiments, one or more of the flow paths 61a, 61b, 61c may have a plurality of heat exchangers to increase the heat transfer that occurs therein. The first flow path 61a of the cooling system 60 may include a first heat exchanger 100a thermally coupled to first heat-generating device 62a via the first heat sink 69a, the second flow path 61b of the cooling system 60 may include a second heat exchanger 100b thermally coupled to second heat-generating device 62b via the second heat sink 69b and the third flow path 61c of the cooling system 60 may include a third heat exchanger 100c thermally coupled to the third heat-generating device 62c via the third heat sink 69c. Each heat exchanger 100a, 100b, 100c may be thermally coupled, and in some embodiments mechanically coupled, to a respective heat sink 69a, 69b, 69c via a thermal interface material as previously described herein. It should be appreciated that embodiments where a single heat exchanger 100 is thermally coupled to the plurality of fluid circuits 77a, 77b, 77c of the plurality of heat sinks 69a, 69b, 69c are also contemplated herein.

Each heat exchanger 100a, 100b, 100c may have a configuration substantially identical to the heat exchanger 100 illustrated and described with reference to FIGS. 1-5. Each heat exchanger 100a, 100b, 100c is configured to receive at least one cooling fluid. As best shown in FIG. 12, an inlet conduit 102a, 102b, 102c may be fluidly connected to a first fluid inlet 104a, 104b, 104c of the heat exchanger 100a, 100b, 100c and an outlet conduit 106a, 106b, 106c may be fluidly connected to a first fluid outlet 108a, 108b, 108c of a respective heat exchanger 100a, 100b, 100c to form a flow path through the heat exchanger 100a, 100b, 100c for a primary cooling fluid C1. Each heat exchanger 100a, 100b, 100c is also configured to receive a flow of a secondary cooling fluid C2a, C2b, C2c.

The first fluid inlet 104a, 104b, 104c of each heat exchanger 100a, 100b, 100c may be fluidly connected to the same source of primary cooling fluid C1. In an embodiment, the inlet conduits 102a, 102b, 102c and the first fluid inlets 104a, 104b, 104c are disposed along the flow paths 61a, 61b, 61c of the cooling system 60 connected to the refrigeration circuit 22 in parallel. In such embodiments, the primary cooling fluid C1a, C1b, C1c is the refrigeration fluid R. In embodiments where both the heat exchanger 100a, 100b, 100c and the heat sink 69a, 69b, 69c associated with a respective heat-generating device 62a, 62b, 62c are fluidly connected to the refrigeration circuit 22, the portion of refrigeration fluid R provided to each respective flow path 61a, 61b, 61c of the cooling system 60 may be further divided between the heat exchanger 100a, 100b, 100c and the corresponding heat sink69a, 69b, 69c. For example, a first part of the refrigeration fluid R provided to the flow path 61a, 61b, 61c may be delivered to the heat exchanger 100a, 100b, 100c as the primary cooling fluid, and a second part of the refrigeration fluid R provided to the flow path 61a, 61b, 61c may be delivered to the fluid circuit 77a, 77b, 77c of the heat sink 69a, 69b, 69c as the

### Heat Transfer Fluid.

The primary cooling fluid C1a, C1b, C1c and the secondary cooling fluid C2a, C2b, C2c are arranged in a heat exchange relationship at each heat exchanger 100a, 100b, 100c. In an embodiment, each respective flow of primary cooling fluid C1a, C1b, C1c is configured to absorb heat from a corresponding flow of secondary cooling fluid C2a, C2b, C2c at the heat exchanger 100a, 100b, 100c. Each secondary cooling fluid C2a, C2b, C2c may be a flow of air. The flows of secondary cooling fluid C2a, C2b, C2c may be moved by a single fan or other movement mechanism 130, or alternatively, a respective fan or other movement mechanism 130a, 130b, 130c may be associated with a corresponding heat exchanger 100a, 100b, 100c to move the secondary cooling fluid C2a, C2b, C2c through the heat exchanger 100a, 100b, 100c.

In the illustrated, non-limiting embodiment, the flow of refrigeration fluid R provided to one or more of the plurality of parallel flow paths 61a, 61b, 61c of the cooling system 60 is controlled by a valve. For example, a first valve V1 may be associated with a first flow path 61a for cooling a first heat-generating device 62a, a second valve V2 may be associated with a second flow path 61b for cooling a second heat-generating device 62b, and a third valve V3 may be associated with a third flow path 61c for cooling a third heat-generating device 62c. Although each of the valves V1, V2, V3 is illustrated at a location upstream from a respective heat exchanger 100a, 100b, 100c, embodiments where one or more of the valves V1, V2, V3 are arranged downstream from a respective heat exchanger 100a, 100b, 100c are also contemplated herein.

The plurality of valves V1, V2, V3 may be actively controlled to maximize heat removal efficiency of the cooling system 60. For example, each valve V1, V2, V3, may be adjusted to control the flow of refrigeration fluid R provided to each flow path 61a, 61b, 61c of the cooling system 60 based on the thermal load at each heat-generating device 62a, 62b, 62c or of each flow path 61a, 61b, 61c. Accordingly, in embodiments where the cooling demand of one of the heat-generating devices 62a, 62b, 62c is higher than the others, the flow of refrigeration fluid R provided to the flow path associated with the heat-generating device having the increased cooling demand may be increased and the flow of refrigeration fluid R provided to the flow paths associated with heat-generating devices having a decreased cooling demand.

As previously described with reference to FIG. 5, a thermal load or cooling demand of each heat-generating device 62a, 62b, 62c associated with the cooling system 60 may be determined using information collected by one or more sensors, represented schematically at T1, T2, T3. These sensors T1, T2, T3 may be operable to measure a temperature of the refrigeration fluid R, or another fluid, such as the secondary cooling fluid C2a, C2b, C2c for example, at or downstream from an outlet of a respective heat-generating device 62a, 62b, 62c. Alternatively, or in addition, these sensors T1, T2, T3 may be operable to measure a vapor quality of the primary cooling fluid C1a, C1b, C1c and adjust the flow of the primary cooling fluid C1a, C1b, C1c used to cool each heat-generating device 62a, 62b, 62c based on the sensed vapor quality.

In an embodiment, the controller C is operable to control a flow of the heat transfer fluid provided to each of the first fluid circuit 77a, the second fluid circuit 77a, and the third fluid circuit 77c. The controller C may adjust the flow of the heat transfer fluid based on the cooling demand of the heat-generating device 62a, 62b, 62c thermally coupled to each heat sink 69a, 69b, 69c. In embodiments where both the primary cooling fluid C1a, C1b, and C1c and the heat transfer fluid used to cool a respective heat-generating device 62a, 62b, 62c is refrigeration fluid R, the controller may adjust the valves to control not only the flow provided to each flow path 61a, 61b, 61c, but also the first part of the refrigeration fluid R provided to the heat exchanger 100a, 100b, 100c and the second part of the refrigeration fluid R provided to a respective fluid circuit 77a, 77b, 77c.

The term “about” is intended to include the degree of error associated with measurement of the particular quantity based upon the equipment available at the time of filing the application.

The terminology used herein is for the purpose of describing particular embodiments only and is not intended to be limiting of the present disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, element components, and/or groups thereof.

While the present disclosure has been described with reference to an exemplary embodiment or embodiments, it will be understood by those skilled in the art that various changes may be made and equivalents may be substituted for elements thereof without departing from the scope of the present disclosure. In addition, many modifications may be made to adapt a particular situation or material to the teachings of the present disclosure without departing from the essential scope thereof. Therefore, it is intended that the present disclosure not be limited to the particular embodiment disclosed as the best mode contemplated for carrying out this present disclosure, but that the present disclosure will include all embodiments falling within the scope of the claims.

What is claimed is:

1. A cooling system, comprising:
a plurality of heat-generating devices comprising at least a first heat-generating device and a second heat-generating device;
at least one heat sink to which the plurality of heat-generating devices are thermally coupled, the at least one heat sink comprising:
at least one housing;
a first fluid circuit associated with at least the first heat-generating device; and
a second fluid circuit associated with at least the second heat-generating device; and
at least one heat exchanger thermally coupled to the at least one heat sink.

2. The cooling system of claim 1, wherein at least one of the first fluid circuit and the second fluid circuit has a closed loop configuration.

3. The cooling system of claim 1, wherein the first fluid circuit and the second fluid circuit are arranged in parallel relative to a flow of heat transfer fluid.

4. The cooling system of claim 3, wherein the first fluid circuit and the second fluid circuit are fluidly coupled by at least one manifold.

5. The cooling system according to claim 3, further comprising a controller configured to selectively control a flow of a heat transfer fluid within the first fluid circuit and/or the second fluid circuit based on a thermal load at the first heat-generating device and the second heat-generating device.

6. The cooling system of claim 1, wherein the at least one heat sink includes a first heat sink and a second heat sink, and the at least one housing includes a first housing and a second housing, the first fluid circuit being formed in the first housing of the first heat sink and the second fluid circuit being formed in the second housing of the second heat sink.

7. The cooling system of claim 6, wherein the first housing is separate from the second housing.

8. The cooling system of claim 6, wherein the first housing is integrally formed with the second housing.

9. The cooling system of claim 1, wherein the at least one heat exchanger includes a first heat exchanger thermally coupled to the first fluid circuit and a second heat exchanger thermally coupled to the second fluid circuit.

10. The cooling system of claim 9, wherein the first heat exchanger and the second heat exchanger are arranged in parallel relative to a flow of a cooling fluid.

11. The cooling system of claim 9, further comprising at least one sensor for monitoring one or more of: a thermal load at the at least one heat exchanger, an interface between the at least one heat sink and the at least one heat exchanger, and a temperature of at least one of the plurality of heat-generating devices.

12. The cooling system of claim 11, further comprising:
at least one valve adjustable to control a flow of a cooling fluid provided to the first heat exchanger and to the second heat exchanger; and
a controller operable to adjust a position of the at least one valve based on data provided by the at least one sensor.

13. A method of cooling a first heat-generating device and a second heat-generating device, the method comprising:
transferring heat from the first heat-generating device to a heat transfer fluid circulating within a first fluid circuit;
transferring heat from the second heat-generating device to the heat transfer fluid circulating within a second fluid circuit; and
transferring heat from the first fluid circuit and from the second fluid circuit to at least one cooling fluid at at least one heat exchanger thermally coupled to the first fluid circuit and the second fluid circuit.

14. The method of claim 13, wherein the at least one cooling fluid includes a primary cooling fluid and a secondary cooling fluid, the heat being transferred from the first fluid circuit and the second fluid circuit to the primary cooling fluid.

15. The method of claim 14, wherein transferring heat from at least one the first fluid circuit and the second fluid circuit to the at least one cooling fluid at the at least one heat exchanger thermally coupled to the first fluid circuit and the second fluid circuit includes vaporizing at least a portion of the primary cooling fluid within an inlet manifold of the at least one heat exchanger.

16. The method of claim 14, further comprising transferring heat from the secondary cooling fluid to the primary cooling fluid at the at least one heat exchanger.

17. The method of claim 14, wherein the at least one heat exchanger includes a first heat exchanger thermally coupled to the first fluid circuit and a second heat exchanger thermally coupled to the second fluid circuit and the primary cooling fluid is provided to the first heat exchanger and the second heat exchanger in parallel.

18. The method of claim 17, further comprising sensing, via at least one sensor, at least one of a thermal load at the first heat exchanger, a thermal load at the second heat exchanger, a temperature of the first heat-generating device, a temperature of the second heat-generating device, a vapor quality of the primary cooling fluid output from the first heat exchanger, and a vapor quality of the primary cooling fluid output from the second heat exchanger.

19. The method of claim 18, further comprising adjusting, via a controller, at least one valve to control a flow of the primary cooling fluid to a first flow path associated with the first heat exchanger and a second flow path associated with the second heat exchanger.

20. The method of claim 19, wherein the at least one valve is adjusted by the controller based on data from the at least one sensor.
